(19) United States
(12) Patent Application Publication
(10) Pub. No.: US 2024/0006454 A1
(43) Pub. Date: Jan. 4, 2024

(54) BACKSIDE ILLUMINATED IMAGE SENSOR SUBSTRATE AND METHOD FOR MANUFACTURING BACKSIDE ILLUMINATED IMAGE SENSOR

(71) Applicant: WUHAN XINXIN SEMICONDUCTOR MANUFACTURING CO., LTD., Wuhan, Hubei (CN)

(72) Inventors: Yan XIE, Wuhan, Hubei (CN); Sheng HU, Wuhan, Hubei (CN); Hao ZOU, Wuhan, Hubei (CN); Xuanjun LIU, Wuhan, Hubei (CN); Tianjian LIU, Wuhan, Hubei (CN); Guoliang YE, Wuhan, Hubei (CN)

(21) Appl. No.: 18/251,781

(22) PCT Filed: Dec. 17, 2020
(86) PCT No.: PCT/CN2020/137406

§ 371 Date: May 4, 2023

(30) Foreign Application Priority Data
Nov. 26, 2020 (CN) 202011347892.4

(51) Int. Cl. H01L 27/146

(52) U.S. Cl. CPC H01L 27/1464; H01L 27/14685

(57) ABSTRACT

A backside illuminated (BSI) image sensor substrate and a method of manufacturing a BSI image sensor are disclosed. A first nitride layer (9) is formed on a metal material layer (70), and a first dry etching process is then performed on both the first nitride layer (9) and the metal material layer (70). In this way, during the etching of the metal material layer (70), the first nitride layer (9) is bombarded so that nitrogen atoms or nitrogen ions escape from the first nitride layer (9), during the formation of a metal grid layer (7), the escaping nitrogen atoms or nitrogen ions react with the metal on sidewalls of second openings (7a), forming a metal nitride layer which protects the metal grid at the sidewalls of the second openings (7a) from being damaged. As such, the resulting metal grid layer (7) has smooth sidewalls and good morphology.

### TECHNICAL FIELD

The present invention relates to the field of semiconductor technology and, in particular, to a backside illuminated (BSI) image sensor substrate and a method of manufacturing a BSI image sensor.

### BACKGROUND

In a backside illuminated (BSI) sensor, light is incident on a substrate from its back side rather than front side. Because of less light reflection, BSI sensors are able to capture more image signals than their front side illuminated (FSI) counterparts. In currently available ultra-thin stacked (UTS) CMOS image sensors (CIS's), a logical operation die is three-dimensionally integrated with a pixel (photodiode) array die by through silicon vias (TSVs). This not only enables the sensor array to have a larger size and area at a given chip size, but also allows significantly fewer metal interconnects to be provided between the functional dies, resulting in less heat generation, less power consumption, reduced delay and higher chip performance.

A UTS CIS includes a metal grid, which is optically opaque and can prevent optical crosstalk between pixels (photodiodes). The morphology of the metal grid contributes much to performance of the BSI image sensor. However, metal grids fabricated by conventional techniques exhibit suboptimal sidewall morphology.

### SUMMARY OF THE INVENTION

It is an objective of the present invention to provide a backside illuminated (BSI) image sensor substrate and a method of manufacturing a BSI image sensor, which overcome the problems of suboptimal sidewall morphology of metal grids in conventional BSI sensors.

To this end, the present invention provides a BSI image sensor substrate including a substrate and, successively formed on the substrate, a metal material layer and a first nitride layer with a plurality of first openings, which together define a metal grid pattern, wherein the first nitride layer is formed to serve as a mask in a first dry etching process for etching the metal material layer and thereby forming a metal grid layer with a plurality of second openings and to be bombarded during the first dry etching process so that nitrogen atoms or ions escape therefrom and react with the metal material at sidewalls of the second openings to form metal nitride.

Optionally, an angle between the sidewalls of the second openings in the metal grid layer and the substrate may be 850 to 90°.

Optionally, the first nitride layer may be made of a material including silicon nitride or silicon oxynitride.

Optionally, the BSI image sensor substrate may further include a first oxide layer formed on the first nitride layer.

Optionally, the BSI image sensor substrate may further include a second oxide layer formed on the metal material layer and situated between the metal material layer and the first nitride layer.

Optionally, the first nitride layer may have a thickness of 1800 Å to 2200 Å, the first oxide layer may have a thickness of 800 Å to 1000 Å, and the second oxide layer may have a thickness of 400 Å to 600 Å.

Optionally, the BSI image sensor substrate may further include a second nitride material layer and a third oxide material layer, which are successively formed on the substrate and situated between the substrate and the metal material layer, wherein the second nitride material layer serves as an etch stop for an etching process performed on the overlying third oxide material layer.

Optionally, the BSI image sensor substrate may further include a fourth oxide layer formed on the substrate and situated between the substrate and the second nitride material layer.

Optionally, the second nitride material layer may be made of silicon nitride or silicon oxynitride and the third oxide material layer and the fourth oxide layer may be made of silicon oxide.

Optionally, the second nitride material layer may have a thickness of 300 Å to 700 A, the third oxide material layer may have a thickness of 600 Å to 1000 Å and the fourth oxide layer may have a thickness of 1500 Å to 2500 Å.

Optionally, the BSI image sensor substrate may further include a high-k dielectric layer having a dielectric constant greater than 25, which is formed on the substrate and situated between the substrate and the fourth oxide layer.

Optionally, the BSI image sensor substrate may further include a dielectric layer formed on the substrate and situated between the substrate and the high-k dielectric layer.

The above objective is also attained by a method of manufacturing a BSI image sensor, which includes:
providing a substrate;
successively forming a metal material layer and a first nitride layer on the substrate, the first nitride layer having a plurality of first openings, which together define a metal grid pattern;
with the first nitride layer serving as a mask, performing a first dry etching process on both the first nitride layer and the metal material layer so that the etched metal material layer forms a metal grid layer and that the first openings extend further into the metal grid layer and thus form second openings, wherein during the etching of the metal material layer, the first nitride layer is bombarded so that nitrogen atoms or ions escape therefrom and react, during the first dry etching process, with the metal at sidewalls of the second openings to form metal nitride.

Optionally, an angle between the sidewalls of the second openings in the metal grid layer and the substrate may be 850 to 90°.

Optionally, the first dry etching process may utilize a nitrogen-containing gas as a gaseous etchant.

Optionally, the formation of the first nitride layer may include:
successively forming a first nitride material layer and a hard mask layer on the metal material layer, the hard mask layer formed therein with a plurality of first trenches, which together define the metal grid pattern; and
with the hard mask layer serving as a mask, etching the first nitride material layer so that the etched first nitride material forms the first nitride layer and that the first trenches further extend into the first nitride layer and thus form the first openings.

Optionally, the method may further include: prior to the formation of the hard mask layer, forming a first oxide material layer on the first nitride material layer; and before or during the etching of the first nitride material layer with the hard mask layer serving as a mask, with the hard mask layer serving as a mask, etching the first oxide material layer so that the etched first oxide material layer forms a first oxide layer and that the first trenches further extend into the first oxide layer.

Optionally, the method may further include: prior to the formation of the first nitride material layer, forming a second oxide material layer on the first metal material layer; and
during or subsequent to the etching of the first nitride material layer, with the hard mask layer serving as a mask, etching the second oxide material layer so that the etched second oxide material layer forms a second oxide layer and that the first openings further extend into the second oxide layer.

Optionally, the first and second oxide layers may be made of silicon oxide and the first nitride layer of silicon nitride or silicon oxynitride.

Optionally, the metal material layer may be made of tungsten, and the first dry etching process may use a gas mixture of CL₂ and NF₃ as a gaseous etchant.

Optionally, a volume ratio of CL₂ to NF₃ may be 1:1 to 1:5, and the first dry etching process may be performed at a temperature of 55° C. to 65° C., source power of 300 W to 500 W and bias power of 600 W to 800 W.

Optionally, in the first dry etching process, a selectivity ratio of the metal material layer to the first or second oxide layer may be greater than 6:1 and a selectivity ratio of the metal material layer to the first nitride layer may be greater than 3:1.

Optionally, the etching of the first nitride material layer with the hard mask layer serving as a mask may be accomplished by a dry etching process using a gas mixture of CHF₃, CH₃F and O₂ as a gaseous etchant, wherein:
the etching of the first oxide material layer and the second oxide material layer during the etching of the first nitride material layer is accomplished by a dry etching process, and the simultaneous etching of the first oxide material layer, the first nitride material layer and the second oxide material layer is accomplished using a gas mixture of CF₄, CH₂F₂ and O₂ as a gaseous etchant; and
the etching of the second oxide material layer prior to the etching of the first nitride material layer with the hard mask layer serving as a mask or the etching of the first oxide material layer subsequent to the etching of the first nitride material layer is accomplished by a dry etching process, and the first oxide material layer is etched using a gas mixture of C₄F₈ and O₂ as a gaseous etchant.

Optionally, the formation of the hard mask layer may include:
forming a hard mask material layer and a photoresist layer on the first oxide material layer, the photoresist layer having a plurality of second trenches, which together define the metal grid pattern, and with the photoresist layer serving as a mask, etching the hard mask material layer so that the etched hard mask material layer forms the hard mask layer and the second trenches further extend into the hard mask layer and thus form the first trenches.

Optionally, the formation of the photoresist layer may include:
forming a photoresist material layer on the hard mask material layer; and
providing a reticle with the metal grid pattern and performing a photolithography process on the photoresist material layer so that the metal grid pattern is transferred into the photoresist material layer, resulting in the formation of the photoresist layer with the plurality of second trenches.

Optionally, the method may further include: prior to the formation of the photoresist material layer, forming an anti-reflective material layer and a dielectric mask material layer on the hard mask material layer;
prior to the etching of the hard mask layer, with the photoresist layer serving as a mask, successively etching the anti-reflective material layer and the dielectric mask material layer so that the etched anti-reflective material layer and dielectric mask material layer form an anti-reflective layer and a dielectric mask layer, respectively, and that the second trenches further extend into the anti-reflective layer and the dielectric mask layer and removing the photoresist layer; and
during the etching of the hard mask material layer, with the anti-reflective layer and the dielectric mask layer together serving as a mask, performing a second dry etching process on both the anti-reflective layer and the hard mask material layer so that the hard mask material layer is etched to form the hard mask layer and that the anti-reflective layer is gradually etched and removed at the same time as the etching of the hard mask material layer.

Optionally, the second dry etching process may use a gas mixture of carbonyl sulfide and oxygen at a volume ratio of 1:2 as a gaseous etchant.

Optionally, the method may further include: prior to the formation of the metal material layer,
successively forming a fourth oxide layer and a second nitride material layer on the substrate; and
after the metal grid layer is formed by etching the metal material layer, with the first nitride layer serving as a mask, performing a third dry etching process on both the first nitride layer and the second nitride material layer so that portions of the second nitride material layer under the second openings are removed, exposing the fourth oxide layer, that the etched second nitride material layer forms a second nitride layer, and that the first nitride layer is removed.

Optionally, the exposed fourth oxide layer may have a height difference between the highest and lowest points of less than 30 nm.

Optionally, the third dry etching process may be a dry etching process using a gas mixture of CH₂F₂, Ar and O₂ as a gaseous etchant.

Optionally, the method may further include: subsequent to the formation of the second nitride material layer on the substrate, forming a third oxide material layer on the nitride material layer; and
prior to or during the third dry etching process on the first nitride layer and the second nitride material layer, with the first nitride layer serving as a mask, etching the third oxide material layer so that portions of the third oxide material layer under the second openings are removed and that the etched third oxide material layer forms a third oxide layer.

Optionally, when the third oxide material layer is etched prior to the third dry etching process on the first nitride layer and the second nitride material layer, the third dry etching process may use a gas mixture of C₄F₈, C₄F₆, Ar and CO as a gaseous etchant.

Alternatively, when the third oxide material layer is etched during the third dry etching process on the first nitride layer and the second nitride material layer, the third dry etching process may use a gas mixture of CHF₃, Ar and O₂ as a gaseous etchant.

Optionally, prior to the formation of the metal material layer, the method may further include:
successively forming a dielectric layer and a high-k dielectric layer on the substrate, the high-k dielectric layer having a dielectric constant greater than 25.

In the BSI image sensor substrate of the present invention, through forming the first nitride layer on the metal material layer, in the subsequent first dry etching process with the first nitride layer serving as a mask, the first nitride layer is bombarded so that nitrogen atoms or ions escape therefrom and react with the metal at the sidewalls of the resulting second openings, forming metal nitride. In this way, the resulting metal grid layer has smooth sidewalls and good morphology.

### BRIEF DESCRIPTION OF THE DRAWINGS

FIG. 1 is a schematic diagram showing the structure of a backside illuminated (BSI) image sensor substrate according to an embodiment of the present invention.

FIG. 2 is a flowchart of a method of manufacturing a BSI image sensor according to an embodiment of the present invention.

FIGS. 3 to 10 are schematic diagrams showing intermediate structures formed during the fabrication of a BSI image sensor according to an embodiment of the present invention.

List of Reference Numerals in Drawings

| | |
|---|---|
| 1-substrate | 11-pixel layer |
| 2-dielectric layer | |
| 3-high-k dielectric layer | |
| 4-fourth oxide layer | |
| 5-second nitride layer | 50-second nitride material layer |
| 6-third oxide layer | 60-third oxide material layer |
| 7-metal grid layer | 70-metal material layer |
| 8-second oxide layer | 80-second oxide material layer |
| 9-first nitride layer | 90-first nitride material layer |
| 10-first oxide layer | 100-first oxide material layer |
| 11-hard mask layer | 110-hard mask material layer |
| 12-dielectric mask layer | 120 dielectric mask material layer |
| 13-anti-reflective layer | 130-anti-reflective material layer |
| 14-photoresist layer | |
| 9a-first opening | |
| 7a-second opening | |
| 11a-first trench | |
| 14a-second trench | |

### DETAILED DESCRIPTION

The backside illuminated (BSI) image sensor substrate and method proposed in the present invention will be described in greater detail below with reference to the accompanying drawings and to specific embodiments. Advantages and features of the present invention will become more apparent from the following description. Note that the figures are provided in a very simplified form not necessarily drawn to exact scale and for the only purpose of facilitating easy and clear description of the embodiments. In addition, the structures shown in the figures are usually partially representations of their actual counterparts. In particular, as the figures would have different emphases, they are sometimes drawn to different scales.

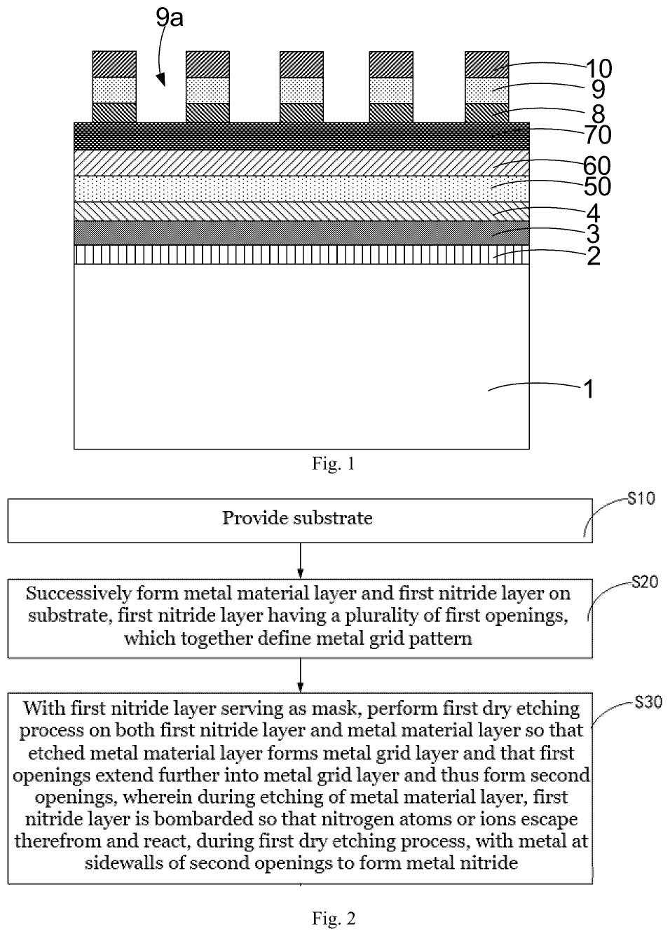

FIG. 1 is a schematic diagram showing the structure of a BSI image sensor substrate according to an embodiment of the present invention. As shown in FIG. 1, the BSI image sensor substrate according to this embodiment includes a substrate 1 and, sequentially formed on the substrate 1, a metal material layer 70 and a first nitride layer 9 with a plurality of first openings 9a, the plurality of first openings 9a together define a metal grid pattern. The first nitride layer 9 is intended to be used as a mask in a first dry etching process for etching the metal material layer 70 and thereby forming a metal grid layer with a plurality of second openings. During the first dry etching process, the first nitride layer 9 is also intended to be bombarded so that nitrogen atoms or ions escape therefrom and react with the metal material on sidewalls of the second openings to form metal nitride.

According to this embodiment, the first nitride layer 9 is formed on the metal material layer 70, and in the subsequent first dry etching process using the first nitride layer 9 as a mask, the first nitride layer 9 is bombarded so that nitrogen atoms or ions escape therefrom and react with the metal on the sidewalls of the resulting second openings to form metal nitride. In this way, the resulting metal grid layer will have smooth sidewalls and good morphology.

In this embodiment, the substrate 1 may have a logic region and a pixel region. A pixel layer consisting of a plurality of pixels may be formed in the pixel region. In this embodiment, the pixel layer may be formed in the substrate 1. In an optional embodiment, the pixels in the pixel layer may alternate with metal grid cells in the metal grid layer. The structure and location of the pixel layer are not particularly limited herein and may be determined as practically needed.

Moreover, in this embodiment, a through silicon via (TSV) process may be employed to form metal interconnects and vias in the logic region of the substrate 1, which enable electrical connection and three-dimensional integration of logical operation circuitry in the logic region with the pixel layer 11 (which is a photoelectric image sensor array) in the pixel region.

Additionally, in this embodiment, the substrate 1 may include semiconductor materials, conductive materials or any combination thereof. It may be either a single- or multi-layer structure. Accordingly, the substrate may be a semiconductor material such as Si, SiGe, SiGeC, SiC, GaAs, InAs, InP or another III/V or II/VI compound semiconductor. Alternatively, it may be implemented as a layered substrate such as, for example, a Si/SiGe, Si/SiC, Si-on-insulator (SOI) or SiGe-on-insulator (SGOI) substrate. The first nitride layer 9 may be a material including silicon nitride or silicon oxynitride.

Further, with continued reference to FIG. 1, the BSI image sensor substrate according to this embodiment may further include a first oxide layer 10 residing on the first nitride layer 9 and a second oxide layer 8 residing on the metal material layer 70 and sandwiched between the metal material layer 70 and the first nitride layer 9. The first oxide layer 10 and the second oxide layer 8 may be each made of a material including silicon oxide. The first nitride layer 9 may have a thickness of 1800 Å to 2200 Å, and the first oxide layer 10 may have a thickness of 800 Å to 1000 Å. The second oxide layer 8 may have a thickness of 400 Å to 600 Å, and the metal material layer 70 may have a thickness of 1800 Å to 2200 Å.

Further, with continued reference to FIG. 1, in this embodiment, the BSI image sensor substrate may further include a second nitride material layer 50 and a third oxide material layer 60, which are sequentially stacked on the substrate 1 and interposed between the substrate 1 and the metal material layer 70. The second nitride material layer 50 is intended to act as an etch stop for an etching process performed on the overlying third oxide material layer 60.

The BSI image sensor substrate may further include a fourth oxide layer 4 formed above the substrate 1 and situated between the substrate 1 and the second nitride material layer 50.

The BSI image sensor substrate may further include a high-k dielectric layer 3 formed above the substrate 1 and situated between the substrate 1 and the fourth oxide layer 4. The fourth oxide layer 4 is formed to protect the high-k dielectric layer 3. The high-k dielectric layer 3 may have a dielectric constant greater than 25. In this embodiment, the high-k dielectric layer 3 may be a metal oxide layer, or formed of an ion-doped non-metallic material. In the former case, the metal oxide layer may include an alumina material layer and a tantala material layer, which are formed successively. The material of the high-k dielectric layer 3 is not particularly limited herein, as long as it can serve to desirably adjust the surface electrical properties of the substrate 1.

The BSI image sensor substrate may further include a dielectric layer 2 residing on the substrate 1 and situated between the substrate 1 and the high-k dielectric layer 3. The dielectric layer 2 may be formed of silicon oxide, the dielectric layer 2 is configured to protect devices within the substrate 1 and isolate the high-k dielectric layer 3 from the substrate 1.

In this embodiment, the second nitride material layer 50 may be a silicon nitride or silicon oxynitride layer, and the third oxide material layer 60 and the fourth oxide layer 4 may be formed of silicon oxide. The second nitride material layer 50 may have a thickness of 300 Å to 700 Å. The third oxide material layer 60 may have a thickness of 600 Å to 1000 Å. The fourth oxide layer 4 may have a thickness of 1500 Å to 2500 Å.

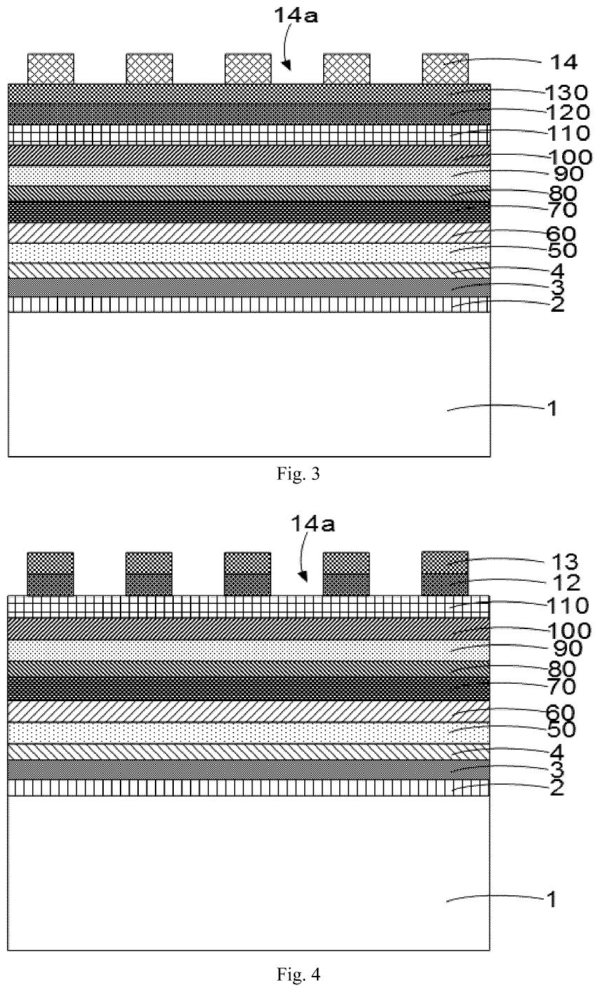

FIG. 2 is a flowchart of a method of manufacturing a BSI image sensor according to an embodiment of the present invention. FIGS. 3 to 10 are schematic diagrams showing intermediate structures formed during the fabrication of a BSI image sensor according to an embodiment of the present invention. Various steps in the method will be described below with reference to FIG. 3 to 10.

In step 810, as shown in FIG. 3, in the present embodiment, a substrate 1 is provided.

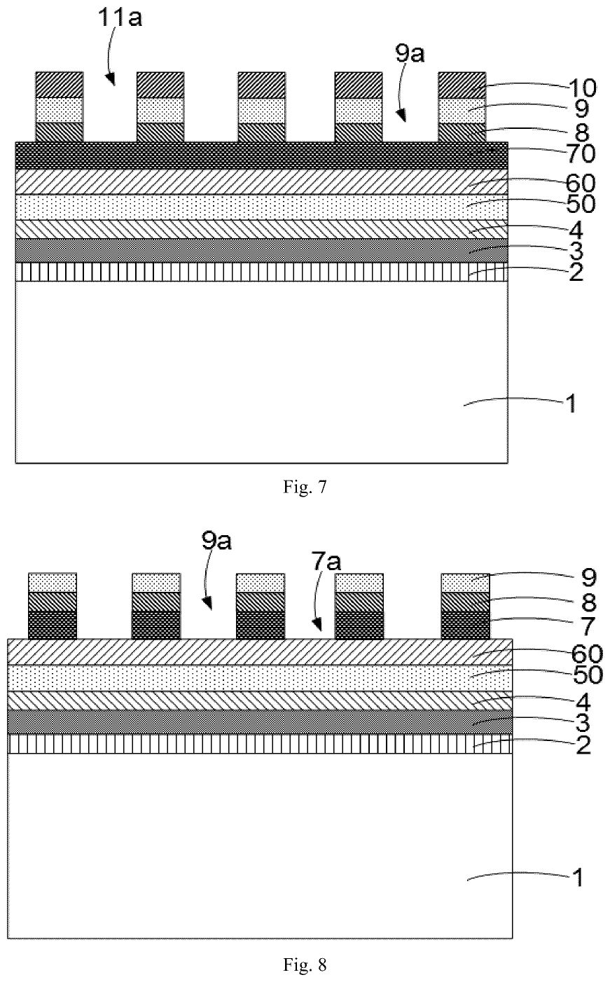

In step 820, referring to FIGS. 7 and 8, a metal material layer 70 and a first nitride layer 9 are successively formed above the substrate 1. The first nitride layer 9 has a plurality of first openings 9a, the plurality of first openings 9a together define a metal grid pattern. In this embodiment, the metal material layer 70 may be formed of tungsten. The first nitride layer 9 may include silicon nitride or silicon oxynitride.

In this embodiment, the formation of the first nitride layer 9 may include steps I and II below.

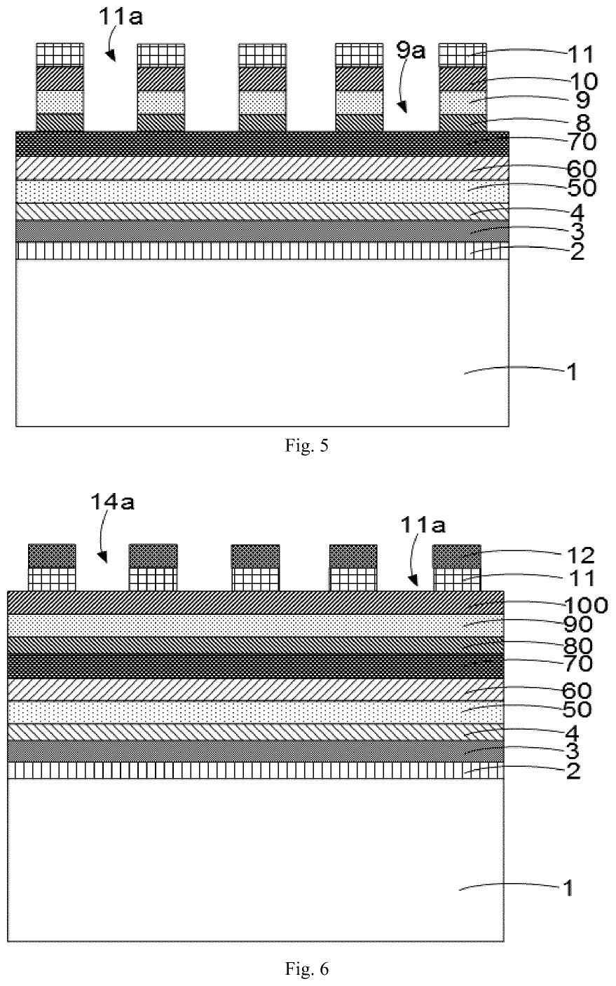

In step I, as shown in FIGS. 4 and 5, a first nitride material layer 90 and a hard mask layer 11 are successively formed over the metal material layer 70, there are a plurality of first trenches 11a in the hard mask layer 11, the plurality of first trenches 11a together define the metal grid pattern. In this embodiment, the hard mask layer 11 may be an advanced patterning film (APF), a spin-on carbon (SOC) layer or an organic dielectric layer (ODL). In this embodiment, the hard mask layer 11 may have a thickness of 4000 Å to 6000 Å.

In step II, with continued reference to FIG. 5, with the hard mask layer 11 serving as a mask, the first nitride material layer 90 is etched to form the first nitride layer 9, and the first trenches 11a are deepened into the first nitride layer 9, resulting in the formation of the first openings 9a.

In this embodiment, the formation of the hard mask layer 11 may include the following steps.

First of all, referring to FIG. 3, a hard mask material layer 110 and a photoresist layer 14 are formed on a first oxide material layer 100. The photoresist layer 14 is formed therein with a plurality of second trenches 14a, the plurality of second trenches 14a together define the metal grid pattern.

Next, with continued reference to FIG. 3, in conjunction with FIGS. 4 and 5, with the photoresist layer 14 as a mask, the hard mask material layer 110 is etched to form the hard mask layer 11, and the second trenches 14a are deepened into the hard mask layer 11, resulting in the formation of the first trenches 11a.

In this embodiment, the formation of the photoresist layer 14 may include the following steps.

At first, with continued reference to FIG. 3, a photoresist material layer is formed on the hard mask material layer 110.

Next, with continued reference to FIG. 3, a reticle with the metal grid pattern is provided, and a photolithography process is performed on the photoresist material layer to transfer the metal grid pattern into the photoresist material layer, thereby forming the photoresist layer 14 with the plurality of second trenches 14a.

Prior to the formation of the photoresist material layer, the method may further include forming an anti-reflective material layer 130 and a dielectric mask material layer 120 over the hard mask material layer 110. The anti-reflective material layer 130 may have a thickness of 300 Å to 500 Å. During the photolithography process for forming the photoresist layer 14, the anti-reflective material layer 130 can enhance light reflection, allowing the use of less optical energy at a given level of quality of the resulting photoresist layer 14 and thus resulting in energy savings.

Further, referring to FIGS. 3 and 4, before the hard mask material layer 110 is etched, the method may further include: with the photoresist layer 14 serving as a mask, successively etching the anti-reflective material layer 130 and the dielectric mask material layer 120 to form an anti-reflective layer 13 and a dielectric mask layer 12, the second trenches 14a extend into both the anti-reflective layer 13 and the dielectric mask layer 12; and removing the photoresist layer 14.

With continued reference to FIGS. 4 and 5, during the etching of the hard mask material layer 110, the method may further include: with the anti-reflective layer 13 and the dielectric mask layer 12 together serving as a mask, performing a second dry etching process on both the anti-reflective layer 13 and the hard mask material layer 110. As a result, the hard mask material layer 110 is etched to form the hard mask layer 11, and at the same time of etching the hard mask material layer 110, the anti-reflective layer 13 is gradually etched away and removed.

Further, in this embodiment, the second dry etching process may use a gaseous etchant consisting of carbonyl sulfide (ocs) and oxygen (O₂) mixed at a volume ratio of 1:2.

Further, with continued reference to FIGS. 4 to 7, in this embodiment, prior to the formation of the hard mask layer 11, the method may further include: forming the first oxide material layer 100 on the first nitride material layer 90; and during or prior to the etching of the first nitride material layer 90 using the hard mask layer 11 as a mask, etching the first oxide material layer 100 also using the hard mask layer 11 as a mask to form a first oxide layer 10, the first trenches 11a are deepened into the first oxide layer 10. In this embodiment, the first oxide layer 10 is formed to protect an underlying metal grid layer 9 formed as a result of etching the metal material layer 90.

Further, with continued reference to FIGS. 4 to 7, in this embodiment, prior to the formation of the first nitride material layer 90, the method may further include forming a second oxide material layer 80 on the first metal material layer 70.

Additionally, during or after the etching of the first nitride material layer 90, with the hard mask layer 11 serving as a mask, the second oxide material layer 80 is etched to form a second oxide layer 8, and the first openings 9a are deepened into the second oxide layer 8.

In this embodiment, the first nitride layer 9 may be formed of silicon nitride or silicon oxynitride, and the first oxide layer 10 and the second oxide layer 8 may be formed of silicon oxide.

Further, in this embodiment, the first nitride material layer 90 may be etched by a dry etching process using the hard mask layer 11 as a mask and using a gaseous etchant, which may be a gas mixture of trifluoromethane (CHF₃), methyl fluoride (CH₃F) and oxygen (O₂), the gas mixture of trifluoromethane (CHF₃), methyl fluoride (CH₃F) and oxygen (O₂) shows a selectivity ratio of greater than 5:1 of the first nitride material layer 90 to the hard mask layer 11. In this way, the hard mask layer 11 is allowed to have a small thickness while still serving the masking purpose, resulting in material savings.

Further, in this embodiment, the second oxide material layer 80 and the first oxide material layer 100 may be etched by a dry etching process during the etching of the first nitride material layer 90. The process for simultaneously etching the second oxide material layer 80, the first nitride material layer 90 and the first oxide material layer 100 may utilize a gaseous etchant, which may be a gas mixture of carbon tetrafluoride (CF₄), difluoromethane (CH₂F₂) and oxygen (O₂).

Further, in this embodiment, with the hard mask layer 11 serving as a mask, the first oxide material layer 100 may be etched before the first nitride material layer 90 is etched, or the second oxide material layer 80 may be etched after the first nitride material layer 90 is etched, by a dry etching process. The second oxide material layer 80 may be etched using a gaseous etchant, which may be a gas mixture of octafluorocyclobutane (C₄F₈) and oxygen (O₂).

As a result of the above steps, the second oxide layer 8, the first nitride layer 9 and the first oxide layer 10 are successively formed over the metal material layer 70 to make up an ONO stack. In optional embodiments, only the first nitride layer 9, or both the first nitride layer 9 and the overlying first oxide layer 10, or both the first nitride layer 9 and the underlying second oxide layer 8 may be formed over the metal material layer 70. The present invention is not limited in this regards, and an appropriate option may be chosen as practically needed.

Further, with continued reference to FIGS. 6 and 7, in this embodiment, after the second oxide layer 8, the first nitride layer 9 and the first oxide layer 10 are successively stacked over the metal material layer 70, the method may further include removing the hard mask layer 11.

In step 830, with continued reference to FIGS. 7 and 8, with the first nitride layer 9 serving as a mask, a first dry etching process is performed on both the first nitride layer 9 and the metal material layer 70. As a result, the metal material layer 70 is etched to form a metal grid layer 7, and the first openings 9a are deepened into the metal grid layer 7, resulting in the formation of second openings 7a. During the etching of the metal material layer 70, the first nitride layer 9 is bombarded so that nitrogen atoms or ions escape therefrom and react with the metal on sidewalls of the resulting second openings 7a during the first dry etching process to form metal nitride.

With continued reference to FIGS. 7 and 8, in this embodiment, the first dry etching process may use a gaseous etchant including a nitrogen-containing gas. In this embodiment, during the first dry etching process, the nitrogen-containing gas contained in the gaseous etchant is also bombarded so that nitrogen atoms or ions escape therefrom, resulting in more nitrogen atoms or ions produced during the etching process and hence a greater amount of metal nitride formed on the sidewalls of the second openings 7a. In this way, the metal grid layer 7 formed in this embodiment will have smoother sidewalls and better morphology.

Further, in this embodiment, during the formation of the metal grid layer 7 by etching the metal material layer 70, the second oxide layer 8, the first nitride layer 9 and the first oxide layer 10 that are successively stacked over the metal material layer 70 may together serve as an etching mask.

Optionally, in case of only the first nitride layer 9 being formed over the metal material layer 70, the metal material layer 70 may be etched using only the first nitride layer 9 as a mask. Alternatively, in case of the second oxide layer 8 and the first nitride layer 9 being successively formed over the metal material layer 70, the may be etched with the second oxide layer 8 and the first nitride layer 9 together serving as a mask. The present invention is not limited in this regard, and an appropriate option may be chosen as practically needed.

Further, in this embodiment, the first dry etching process may be a pulsed dry etching process. According to this embodiment, through using the pulsed dry etching process, any metal material that may build up in the second openings 7a and may therefore possibly affect the etching quality can be removed in a timely way, ensuring good morphology of the resultant metal grid layer 7.

Further, in this embodiment, the gaseous etchant used in the first dry etching process may be a gas mixture of chlorine (CL₂) and chlorine nitrogen trifluoride (NF₃), which may have a selectivity ratio of greater than 6:1 of the metal material layer 70 to the second oxide layer 8 or first oxide layer 10 and a selectivity ratio of greater than 3:1 of the metal material layer 70 to the first nitride layer 9. Such a high selectivity ratio of the metal material layer 70 to the second oxide layer 8 or the first oxide layer 10 enables the second oxide layer 8 or first oxide layer 10 to have a small thickness while still serving the masking purpose, resulting in material savings.

Further, in this embodiment, the first dry etching process may be carried out at a CL₂ to NF₃ volume ratio of 1:1 to 1:5, a temperature of 55° C. to 65° C., source power of 300 W to 500 W and bias power of 600 W to 800 W.

Further, with continued reference to FIG. 8, an angle of the sidewalls of the second openings 7a in the resulting metal grid layer 7 and the substrate may be 85° to 90°. Thus, the sidewalls of the second openings 7a formed in accordance with the method of this embodiment are substantially perpendicular to the substrate and have the best morphology.

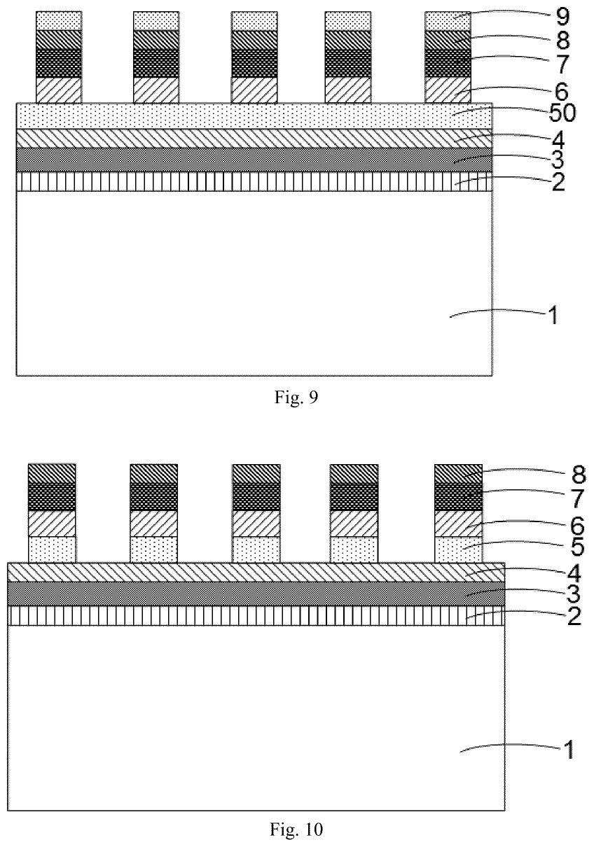

Further, with continued reference to FIGS. 7 to 8, in conjunction with FIGS. 9 and 10, in this embodiment, before the formation of the metal material layer 70, the method may further include successively forming a dielectric layer 2 and a high-k dielectric layer 3 over the substrate 1. The high-k dielectric layer 3 may have a dielectric constant greater than 25. In this embodiment, the high-k dielectric layer 3 may be a metal oxide layer, or formed of an ion-doped non-metallic material. In the former case, the metal oxide layer may include an alumina material layer and a tantala material layer, which are formed successively. The material of the high-k dielectric layer 3 is not particularly limited herein, as long as it can serve to desirably adjust the surface electrical properties of the substrate 1. The dielectric layer 2 may be formed of silicon oxide. The dielectric layer 2 is configured to protect devices within the substrate 1 and isolate the high-k dielectric layer 3 from the substrate 1.

In this embodiment, prior to the formation of the metal material layer 90, the method may further include forming a fourth oxide layer 4 and a second nitride material layer 50 over the substrate 1. Moreover, after the metal grid layer 7 is formed by etching the metal material layer 70, the method may further include, with the first nitride layer 9 serving as a mask, performing a third dry etching process on both the first nitride layer 9 and the second nitride material layer 50. As a result, the second nitride material layer 50 under the second openings 7a is removed, exposing the fourth oxide layer 4 and forming a second nitride layer 5. At the same time, the first nitride layer 9 may be removed. The third dry etching process may be a dry etching process using a gaseous etchant, which may be a gas mixture of difluoromethane (CH₂F₂), argon (Ar) and oxygen (O₂). The third dry etching process may be carried out at a 50° C. to 70° C. and a pressure of 30 mt to 40 mt. In this embodiment, during the third dry etching process on the first nitride layer 9 and the second nitride material layer 50, due to the presence of the second nitride material layer 50 between the fourth oxide layer 4 and the metal grid layer 7, as well as to a relative high selectivity ratio of the fourth oxide layer 4 to the first nitride layer 9, as a result of etching the second nitride material layer 50, the exposed fourth oxide layer 4 will have a flat top surface with a height difference between the highest and lowest points of 30 nm or less.

After the second nitride material layer 50 is formed over the substrate 1, the method may further include forming a third oxide material layer 60 on the nitride material layer 50.

Moreover, before or at the same time when the third dry etching process is performed on both the first nitride layer 9 and the second nitride material layer 5, the method may further include, with the first nitride layer 9 serving as a mask, etching the third oxide material layer 60 to remove portions of the third oxide material layer 60 underlying the second openings 7a, thereby forming a third oxide layer 6.

When the third oxide material layer 60 is etched before the third dry etching process is carried out on both the first nitride layer 9 and the second nitride material layer 50, the etching may be accomplished by a dry etching process, and the third dry etching process may use a gaseous etchant, which may be a gas mixture of octafluorocyclobutane (C₄F₈), perfluorobutadiene (C₄F₆), oxygen (O₂), argon (Ar) and carbon monoxide (CO). The etching process may be performed at a temperature of 50° C. to 70° C. and a pressure of pressure of 30 mt to 50 mt. The gaseous etchant used in the third dry etching process may exhibit a high selectivity ratio to the third oxide material layer 60. As a result of the etching process, the second nitride material layer 50 underlying the third oxide material layer 60 will have a flat top surface, and the fourth oxide layer 4 underlying the second nitride material layer 50 will not be overly damaged during the subsequent etching of the second nitride material layer 50. This allows even higher flatness of a top surface of the fourth oxide layer 4 exposed as a result of etching the second nitride material layer 50.

When the third oxide material layer 60 is etched in the course of the third dry etching process on both the first nitride layer 9 and the second nitride material layer 50, the third dry etching process may utilize a gaseous etchant, which may be a gas mixture of trifluoromethane (CHF₃), argon (Ar) and oxygen (O₂).

The description presented above is merely that of a few preferred embodiments of the present invention and does not limit the scope thereof in any sense. Any and all changes and modifications made by those of ordinary skill in the art based on the above teachings fall within the scope as defined in the appended claims.

1. A backside illuminated (BSI) image sensor substrate, comprising a substrate and, successively formed on the substrate, a metal material layer and a first nitride layer with a plurality of first openings, a pattern of the plurality of first openings defining a metal grid pattern,
wherein the first nitride layer is configured to perform a first dry etching process using the first nitride layer as a mask to etch the metal material layer, thereby forming a metal grid layer with a plurality of second openings, the first nitride layer is also configured to be bombarded to escape nitrogen atoms or nitrogen ions when the first dry etching process is performed, so as to react with the metal material at sidewalls of the second openings to form metal nitride.

2. The BSI image sensor substrate of claim 1, wherein an angle between the sidewalls of the second openings in the metal grid layer and the substrate is 85° to 90°, and/or
wherein the first nitride layer is made of a material comprising silicon nitride or silicon oxynitride.

3. (canceled)

4. The BSI image sensor substrate of claim 1, further comprising a first oxide layer on the first nitride layer and a second oxide layer formed on the metal material layer and situated between the metal material layer and the first nitride layer.

5. (canceled)

6. The BSI image sensor substrate of claim 1, further comprising a second nitride material layer and a third oxide material layer, which are successively formed on the substrate and situated between the substrate and the metal material layer, the second nitride material layer serving as an etch stop for an etching process performed on the overlying third oxide material layer.

7. The BSI image sensor substrate of claim 6, further comprising a fourth oxide layer formed on the substrate and situated between the substrate and the second nitride material layer.

8. The BSI image sensor substrate of claim 7, wherein the second nitride material layer is made of silicon nitride or silicon oxynitride and the third oxide material layer and the fourth oxide layer are made of silicon oxide, and/or
wherein the second nitride material layer has a thickness of 300 Å to 700 Å, the third oxide material layer has a thickness of 600 Å to 1000 Å and the fourth oxide layer has a thickness of 1500 Å to 2500 Å.

9. (canceled)

10. The BSI image sensor substrate of claim 7, further comprising:
a high-k dielectric layer formed on the substrate and situated between the substrate and the fourth oxide layer, the high-k dielectric layer having a dielectric constant greater than 25; and
a dielectric layer formed on the substrate and situated between the substrate and the high-k dielectric layer.

11. A method of manufacturing a backside illuminated (BSI) image sensor, comprising:
providing a substrate;
successively forming a metal material layer and a first nitride layer on the substrate, the first nitride layer having a plurality of first openings, a pattern of the plurality of first openings defining a metal grid pattern;
with the first nitride layer serving as a mask, performing a first dry etching process on both the first nitride layer and the metal material layer, etching the metal material layer to form a metal grid layer and extending the first openings into the metal grid layer to form second openings, wherein during the etching of the metal material layer, the first nitride layer is bombarded to escape nitrogen atoms or nitrogen ions from the first nitride layer, during the first dry etching process, the nitrogen atoms or the nitrogen ions react with the metal at sidewalls of the second openings to form metal nitride.

12. The method of manufacturing a BSI image sensor of claim 11, wherein an angle between the sidewalls of the second openings in the metal grid layer and the substrate is 85° to 90°, and/or
prior to the formation of the metal material layer, the method further comprising successively forming a dielectric layer and a high-k dielectric layer on the substrate, the high-k dielectric layer having a dielectric constant greater than 25.

13. The method of manufacturing a BSI image sensor of claim 11, wherein the formation of the first nitride layer comprises:
successively forming a first nitride material layer and a hard mask layer on the metal material layer, the hard mask layer formed therein with a plurality of first trenches, the plurality of first trenches together define the metal grid pattern; and
with the hard mask layer serving as a mask, etching the first nitride material layer to form the first nitride layer and extending the first trenches further into the first nitride layer to form the first openings.

14. The method of manufacturing a BSI image sensor of claim 13, further comprising: prior to the formation of the hard mask layer, forming a first oxide material layer on the first nitride material layer;
before or during the etching of the first nitride material layer with the hard mask layer serving as a mask, with the hard mask layer serving as a mask, etching the first oxide material layer to form a first oxide layer and extending the first trenches into the first oxide layer;
prior to the formation of the first nitride material layer, forming a second oxide material layer on the first metal material layer; and
during or subsequent to the etching of the first nitride material layer, with the hard mask layer serving as a mask, etching the second oxide material layer to form a second oxide layer and extending the first openings into the second oxide layer.

15. The method of manufacturing a BSI image sensor of claim 14, wherein the first and second oxide layers are made of silicon oxide, the first nitride layer of silicon nitride or silicon oxynitride and the metal material layer of tungsten.

16. The method of manufacturing a BSI image sensor of claim 15, wherein the first dry etching process uses a gas mixture of CL₂ and NF₃, the gas mixture of CL₂ and NF₃ has a volume ratio of 1:1 to 1:5, and the first dry etching process is performed at a temperature of 55° C. to 65° C., source power of 300 W to 500 W and bias power of 600 W to 800 W, and/or
wherein in the first dry etching process, a selectivity ratio of the metal material layer to the first or second oxide layer is greater than 6:1 and a selectivity ratio of the metal material layer to the first nitride layer is greater than 3:1.

17. (canceled)

18. The method of manufacturing a BSI image sensor of claim 15, the etching of the first nitride material layer with the hard mask layer serving as a mask is accomplished by a dry etching process using a gas mixture of CHF₃, CH₃F and O₂ as a gaseous etchant;
the etching of the first oxide material layer and the second oxide material layer during the etching of the first nitride material layer is accomplished by a dry etching process, and the simultaneous etching of the first oxide material layer, the first nitride material layer and the second oxide material layer is accomplished using a gas mixture of CF₄, CH₂F₂ and O₂ as a gaseous etchant; and
the etching of the second oxide material layer prior to the etching of the first nitride material layer with the hard mask layer serving as a mask or the etching of the first oxide material layer subsequent to the etching of the first nitride material layer is accomplished by a dry etching process, and the first oxide material layer is etched using a gas mixture of C₄F₈ and O₂ as a gaseous etchant.

19. The method of manufacturing a BSI image sensor of claim 11, wherein the formation of the hard mask layer comprises:
forming a hard mask material layer and a photoresist layer on the first oxide material layer, the photoresist layer having a plurality of second trenches, a pattern of the plurality of second openings defining the metal grid pattern, and
with the photoresist layer serving as a mask, etching the hard mask material layer to form the hard mask layer and extending the second trenches into the hard mask layer to form the first trenches,
the formation of the photoresist layer comprising:
forming a photoresist material layer on the hard mask material layer; and
providing a reticle with the metal grid pattern and performing a photolithography process on the photoresist material layer so that the metal grid pattern is transferred into the photoresist material layer, thereby forming the photoresist layer with the plurality of second trenches.

20. The method of manufacturing a BSI image sensor of claim 19, further comprising: prior to the formation of the photoresist material layer, forming an anti-reflective material layer and a dielectric mask material layer on the hard mask material layer;
prior to the etching of the hard mask layer, with the photoresist layer serving as a mask, successively etching the anti-reflective material layer and the dielectric mask material layer so that the etched anti-reflective material layer and dielectric mask material layer form an anti-reflective layer and a dielectric mask layer, respectively, and extending the second trenches into the anti-reflective layer and the dielectric mask layer and removing the photoresist layer; and
during the etching of the hard mask material layer, with the anti-reflective layer and the dielectric mask layer together serving as a mask, performing a second dry etching process on both the anti-reflective layer and the hard mask material layer, etching the hard mask material layer to form the hard mask layer and etching the anti-reflective layer to gradually remove the anti-reflective layer at the same time as the etching of the hard mask material layer.

21. (canceled)

22. The method of manufacturing a BSI image sensor of claim 11, further comprising: prior to the formation of the metal material layer,
successively forming a fourth oxide layer and a second nitride material layer on the substrate; and
after the metal grid layer is formed by etching the metal material layer, with the first nitride layer serving as a mask, performing a third dry etching process on both the first nitride layer and the second nitride material layer so that portions of the second nitride material layer under the second openings are removed, exposing the fourth oxide layer, the etched second nitride material layer forming a second nitride layer, and removing the first nitride layer.

23. The method of manufacturing a BSI image sensor of claim 22,
wherein the exposed fourth oxide layer has a height difference between highest and lowest points of less than 30 nm, the third dry etching process is a dry etching process, the third dry etching process using a gas mixture of CH₂F₂, Ar and O₂ as a gaseous etchant.

24. The method of manufacturing a BSI image sensor of claim 22, further comprising: subsequent to the formation of the second nitride material layer on the substrate, forming a third oxide material layer on the nitride material layer; and
prior to or during the third dry etching process on the first nitride layer and the second nitride material layer, with the first nitride layer serving as a mask, etching the third oxide material layer to remove portions of the third oxide material layer under the second openings, thereby forming a third oxide layer.

25. The method of manufacturing a BSI image sensor of claim 24, when the third oxide material layer is etched prior to the third dry etching process on the first nitride layer and the second nitride material layer, the third dry etching process uses a gas mixture of C₄F₈, C₄F₆, Ar and CO as a gaseous etchant, and
when the third oxide material layer is etched during the third dry etching process on the first nitride layer and the second nitride material layer, the third dry etching process uses a gas mixture of CHF₃, Ar and O₂ as a gaseous etchant.

26. (canceled)
